(19) United States
(12) Patent Application Publication
(10) Pub. No.: US 2024/0178144 A1
(43) Pub. Date: May 30, 2024

(54) INTERCONNECT STRUCTURE AND ELECTRONIC DEVICE INCLUDING THE SAME

(71) Applicant: Samsung Electronics Co., Ltd., Suwon-si (KR)

(72) Inventors: Keunwook SHIN, Suwon-si (KR); Hyeonjin SHIN, Suwon-si (KR); Sangwon KIM, Suwon-si (KR); Changhyun KIM, Suwon-si (KR); Baekwon PARK, Suwon-si (KR); Kyung-Eun BYUN, Suwon-si (KR)

(73) Assignee: Samsung Electronics Co., Ltd., Suwon-si, (KR)

(21) Appl. No.: 18/521,994

(22) Filed: Nov. 28, 2023

(30) Foreign Application Priority Data
Nov. 29, 2022 (KR) 10-2022-0163251

(51) Int. Cl. H01L 23/532

(52) U.S. Cl. CPC H01L 23/53276; H01L 23/53295

(57) ABSTRACT

An interconnect structure may include a first dielectric layer including a trench, a first conductive layer in the trench and including a plurality of first graphene layers stacked in a direction from an inner surface of the trench toward a center of the trench, a second dielectric layer on the first dielectric layer and including a through hole extending to the trench, and a second conductive layer in the through hole.

### CROSS-REFERENCE TO RELATED APPLICATION

This application is based on and claims priority under 35 U.S.C. § 119 to Korean Patent Application No. 10-2022-0163251, filed on Nov. 29, 2022, in the Korean Intellectual Property Office, the disclosure of which is incorporated by reference herein in its entirety.

### BACKGROUND

### 1. Field

The disclosure relates to an interconnect structure and an electronic device including the same.

### 2. Description of the Related Art

For higher integration of semiconductor devices, the size of the semiconductor devices is gradually decreasing, and accordingly, a line width of wires in an interconnect structure is also decreasing to the nano-scale.

To form nano-scale wires, a photolithography process for nano-patterning is performed, and here, misalignment or overlay, etc. may occur. In addition, when realizing fine line widths, the resistivity of a wire material may increase, causing a rapid increase in the resistivity of the wire. Thus, a method for forming fine wires with low resistance and without misalignment is continuously researched.

### SUMMARY

Provided are an interconnect structure and an electronic device including the same.

Additional aspects will be set forth in part in the description which follows and, in part, will be apparent from the description, or may be learned by practice of the presented embodiments of the disclosure.

According to an example embodiment, an interconnect structure may include a first dielectric layer including a trench; a first conductive layer in the trench, the first conductive layer including a plurality of first graphene layers stacked in a direction from an inner surface of the trench toward a center of the trench; a second dielectric layer on the first dielectric layer, the second dielectric layer including a through hole extending to the trench; and a second conductive layer in the through hole.

In some embodiments, the second conductive layer may include a plurality of second graphene layers.

In some embodiments, the second conductive layer may include a metal material.

In some embodiments, the first conductive layer may further include a metal layer contacting the inner surface of the trench.

In some embodiments, the second conductive layer may include a plurality of second graphene layers.

In some embodiments, the second conductive layer may include a metal material.

In some embodiments, the first dielectric layer may include a dielectric material having a dielectric constant of 3.6 or less.

In some embodiments, the second dielectric layer may include a dielectric material that is selectively depositable on the first dielectric layer.

In some embodiments, the interconnect structure may further include a third dielectric layer on the second dielectric layer. The second dielectric layer and the third dielectric layer may define the through hole such that through hole extends through the second dielectric layer to the third dielectric layer and penetrates through the third dielectric layer. The second conductive layer may fill the through hole.

In some embodiments, the third dielectric layer may include a dielectric material having a dielectric constant of 3.6 or less.

In some embodiments, a width of the trench may be equal to or less than 10 nm.

In some embodiments, the plurality of first graphene layers may include intrinsic graphene or nanocrystalline graphene.

In some embodiments, the nanocrystalline graphene may include crystals having a size of about 0.5 nm to about 500 nm.

In some embodiments, in the nanocrystalline graphene, a ratio of carbons having an sp² bond structure to total carbons may be about 50% to about 99%.

In some embodiments, the nanocrystalline graphene may include hydrogen of about 1 at % to about 20 at %.

In some embodiments, the nanocrystalline graphene may have a density of about 1.6 g/cc to about 2.1 g/cc.

In some embodiments, surface of crystals of the nanocrystalline graphene is substantially perpendicular to a direction of stacking of the plurality of the first graphene layers.

According to an example embodiment, an electronic device may include substrate and an interconnect structure on the substrate. The interconnect structure may include a first dielectric layer including a trench, a first conductive layer in the trench, a second dielectric layer on the first dielectric layer, and a second conductive layer. The first conductive layer may include a plurality of first graphene layers stacked in a direction from an inner surface of the trench toward a center of the trench. The second dielectric layer may include a through hole extending to the trench. The second conductive layer may be in the through hole.

In some embodiments, the second conductive layer may include a plurality of graphene layers or a metal material.

In some embodiments, the interconnect structure may further include a third dielectric layer on the second dielectric layer. The second dielectric layer and the third dielectric layer may define the through hole such that the through hole extends through the second dielectric layer to the third dielectric layer and penetrates through the third dielectric layer. The second conductive layer may fill the through hole.

In some embodiments, the width of the trench may be equal to or less than 10 nm.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a schematic structure of an interconnect structure according to an embodiment;

FIG. 2 is a cross-sectional view illustrating a schematic structure of an interconnect structure according to a comparative example;

FIG. 3 is a microscopic photograph of a graphene layer included in the interconnect structure of FIG. 2;

FIG. 4 is a graph showing a concept of a relationship between a width and resistivity of a graphene layer in the interconnect structure of FIG. 2;

FIG. 5 is a cross-sectional view illustrating a schematic structure of an interconnect structure according to another embodiment;

FIG. 6 is a cross-sectional view illustrating a schematic structure of an interconnect structure according to another embodiment;

FIG. 7 is a cross-sectional view illustrating a schematic structure of an interconnect structure according to another embodiment;

FIGS. 8A to 8I are diagrams for describing a method of manufacturing an interconnect structure, according to an embodiment;

FIG. 9 is a cross-sectional view of a memory device according to an embodiment;

FIG. 10 is a cross-sectional view of an image sensor according to an embodiment; and

FIG. 11 is a diagram of an electronic device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Reference will now be made in detail to embodiments, examples of which are illustrated in the accompanying drawings. The embodiments described herein may have different forms and should not be construed as being limited to the descriptions set forth herein. In the drawings, like reference numerals refer to like elements throughout and sizes of constituent elements may be exaggerated for convenience of explanation and the clarity of the specification.

It will also be understood that when an element is referred to as being “on” or “above” another element, the element may be in direct contact with the other element or other intervening elements may be present.

While such terms as “first,” “second,” etc., may be used to describe various elements, such elements must not be limited to the above terms. The above terms are used only to distinguish one element from another. The terms do not define difference in the material or structure of the elements.

The singular forms include the plural forms unless the context clearly indicates otherwise. It should be understood that, when a part “comprises” or “includes” an element, unless otherwise defined, other elements are not excluded from the part and the part may further include other elements.

Also, in the specification, the term “. . . units” or “. . . modules” denote units or modules that process at least one function or operation, and may be realized by hardware, software, or a combination of hardware and software.

The use of the terms “a” and “an” and “the” and similar referents are to be construed to cover both the singular and the plural.

The steps of all methods described herein can be performed in any suitable order unless otherwise indicated herein or otherwise clearly contradicted by context. The use of any and all examples, or example language (e.g., “such as”) provided herein, is intended merely to better illuminate the disclosure and does not pose a limitation on the scope of the disclosure unless otherwise claimed.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

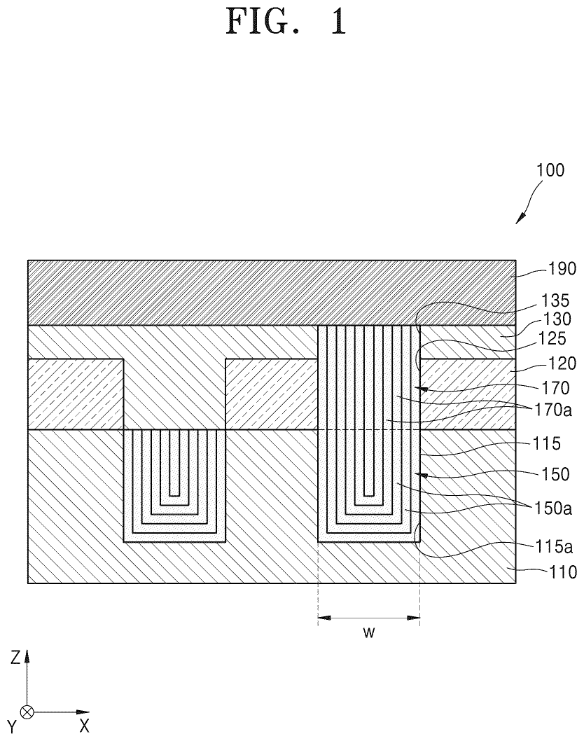

FIG. 1 is a cross-sectional view illustrating a schematic structure of an interconnect structure according to an embodiment.

An interconnect structure 100 includes a first dielectric layer 110 having a trench 115 formed therein, a first conductive layer 150 formed in the trench 115 and including a plurality of graphene layers 150a, a second dielectric layer 120 formed on the first dielectric layer 110 and having a through hole 125 connected to the trench 115 of the first dielectric layer 110, and a second conductive layer 170 formed in the through hole 125.

The first dielectric layer 110 is an inter-metal dielectric (IMD) and may include a conventional low-k dielectric material. The first dielectric layer 110 may include a dielectric material having a dielectric constant of about 3.6 or less. The first dielectric layer 110 may include Al₂O₃, AlN, ZrO₂, HfOₓ (0<x<4), SiO₂, SiCO, SiCN, SiON, SiCOH, AlSiO, or boron nitride (BN). However, without limitations thereto, various other dielectric materials may be used for the first dielectric layer 110. Also, the first dielectric layer 110 may include an organic dielectric material.

The trench 115 may be recessed to a desired and/or alternatively predetermined depth from an upper surface of the first dielectric layer 110, and formed by, for example, a photolithography process and an etching process such as reactive ion etching (RIE). As illustrated in the drawing, the trench 115 may have a depth at which a bottom surface thereof is formed within the first dielectric layer 110, or a depth to reach another element or wire that may be located under the first dielectric layer 110 by entirely penetrating the first dielectric layer 110. For example, the depth of the trench 115 may not be constant, and the trench 115 may have a different depth in a cross-section different from the illustrated cross-section, that is, in a cross-section having a different position in a Y-direction. A width w of the trench 115 in a direction perpendicular to the depth direction (Z-direction) (X-direction) may be several to several tens of nm. For example, the width w may be about 20 nm or less or about 10 nm or less. Two trenches 115 are illustrated as an example, and a different number of trenches 115 may also be provided. In addition, a plurality of trenches 115 having different widths or depths may be provided.

The first conductive layer 150 is provided inside the trench 115. The first conductive layer 150 may be formed to fill the trench 115. The first conductive layer 150 includes the plurality of graphene layers 150a. The plurality of graphene layers 150a may be stacked in a direction from an inner surface 115a of the trench 115 toward a center of the trench 115. A first graphene layer 150a may be conformally formed along the inner surface 115a of the trench 115, that is, along inner side surfaces and an inner bottom surface of the trench 115, and then, a second graphene layer 150a may be conformally formed along a surface of the first graphene layer 150a, and in this manner, the plurality of graphene layers 150a may be formed and an inner portion of the trench 115 may be filled.

The second dielectric layer 120 may be arranged on the first dielectric layer 110. The through hole 125 may be formed in the second dielectric layer 120, and the through hole 125 may be connected to the trench 115 of the first dielectric layer 110.

The second dielectric layer 120 may include a dielectric material having various dielectric constants. For example, the second dielectric layer 120 may include Al₂O₃, AlN, ZrO₂, HfOₓ, SiO₂, SiCO, SiCN, SiON, SiCOH, AlSiO, or boron nitride (BN). However, the disclosure is not limited thereto. The second dielectric layer 120 may include a dielectric material that can be deposited selectively on the first dielectric layer 110. Accordingly, the through hole 125 well aligned with the trench 115 formed in the first dielectric layer 110 may be formed in the second dielectric layer 120. The above-described process is referred to as a fully-aligned via (FAV) process, and may be used to reduce problems such as misalignment or overlap when performing a photolithography process for forming nano-scale wires. In the FAV process, a graphene material used to form the first conductive layer 150 may also act as a self-inhibitor, and thus, the formation of the second dielectric layer 120 may be easier in the FAV process. This will be described again in the description of a manufacturing method. Various materials may be set as a material of the second dielectric layer 120 in accordance with the FAV process.

The second conductive layer 170 may be formed in the through hole 125. The second conductive layer 170 may be formed to be connected to the first conductive layer 150. The second conductive layer 170 may also include a plurality of graphene layers 170a. The plurality of graphene layers 170a constituting the second conductive layer 170 are shown as being aligned with the plurality of graphene layers 150a constituting the first conductive layer 150, but this is an example, and the graphene layers 150a of the first conductive layer 150 and the graphene layers 170a of the second conductive layer 170 may not be completely aligned with each other and may be slightly offset from each other.

A third dielectric layer 130 having a through hole 135 connected to the through hole 125 of the second dielectric layer 120 may be formed on the second dielectric layer 120, and the second conductive layer 170 may be formed to extend to the through hole 135.

A third conductive layer 190 connected to the second conductive layer 170 may be formed on the third dielectric layer 130. The third conductive layer 190 may include various conductive materials. The third conductive layer 190 may include various metal materials such as Cu, Ru, Rh, Ir, Mo, W, Pd, Pt, Co, Ta, Ti, Ni, or Pd, or may include graphene.

The third dielectric layer 130 becomes an inter-metal dielectric (IMD) of a different level from that of the first dielectric layer 110. Similar to the first dielectric layer 110, the third dielectric layer 130 may include a low-k dielectric material, and may include a dielectric material having a dielectric constant of about 3.6 or less. The third dielectric layer 130 may include various dielectric materials applicable to the first dielectric layer 110.

As described above, a material suitable for the FAV process is set for the second dielectric layer 120, and in this case, when the second dielectric layer 120 may have also low-k properties suitable for an interlayer insulating film, the third dielectric layer 130 may be omitted. That is, in this case, the second dielectric layer 120 may act both as an interlayer insulating film and as a dielectric film for the FAV process.

The graphene layers 150a of the first conductive layer 150 and the graphene layers 170a of the second conductive layer 170 may include carbon atoms having an sp² bond structure, and may include, for example, graphene. Graphene refers to a material having a hexagonal honeycomb structure in which carbon atoms are connected in two dimensions. Graphene may include intrinsic graphene or nanocrystalline graphene. Graphene may include metal-doped graphene or undoped graphene.

Intrinsic graphene, also referred to as crystalline graphene, may include crystals having a size greater than about 100 nm. In intrinsic graphene, a ratio of carbons having an sp² bonding structure to total carbons may be almost 100%. And, intrinsic graphene may hardly contain hydrogen. In addition, a density of intrinsic graphene may be, for example, about 2.1 g/cc.

Nanocrystalline graphene may include smaller crystals than intrinsic graphene. Nanocrystalline graphene may include, for example, crystals having a size ranging from about 0.5 nm to about 500 nm, and may include crystals having a size of about 100 nm or less. In nanocrystalline graphene, a ratio of carbons having an sp² bond structure to total carbons may be about 50% to about 99%. Nanocrystalline graphene may contain about 1 at % to about 20 at % hydrogen. Nanocrystalline graphene may have a density of about 1.6 g/cc to about 2.1 g/cc. Sheet resistance of nanocrystalline graphene may be greater than about 1000 Ohm/sq, for example. However, this is an example, and the disclosure is not limited thereto. In case that the graphene layers 150a or the graphene layers 170a includes nanocrystalline graphene, the surface of crystals is substantially perpendicular to the direction of stacking of the graphene layers 150a or 170a.

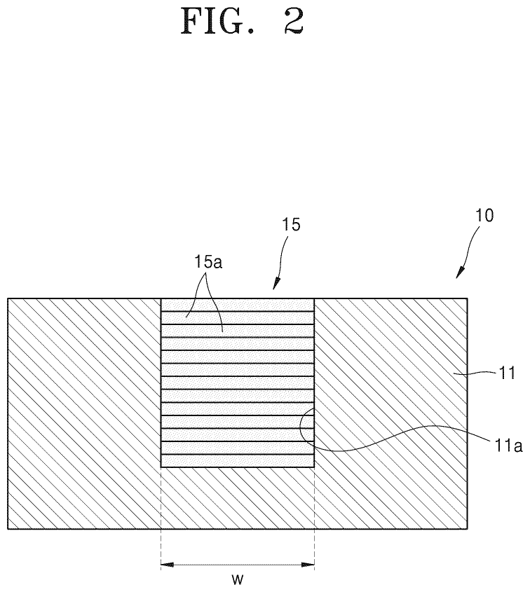

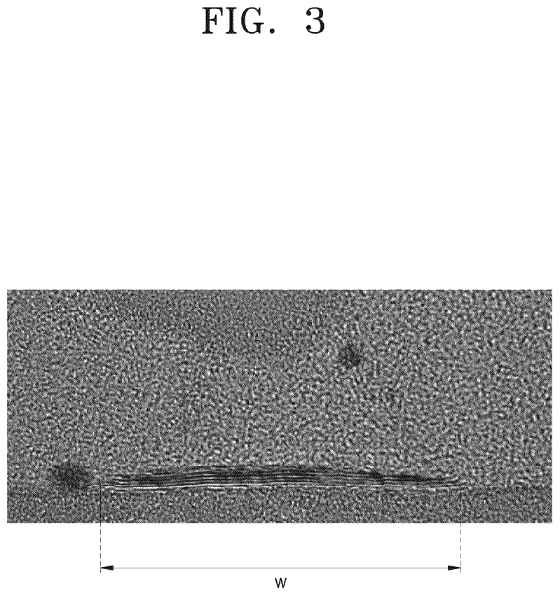

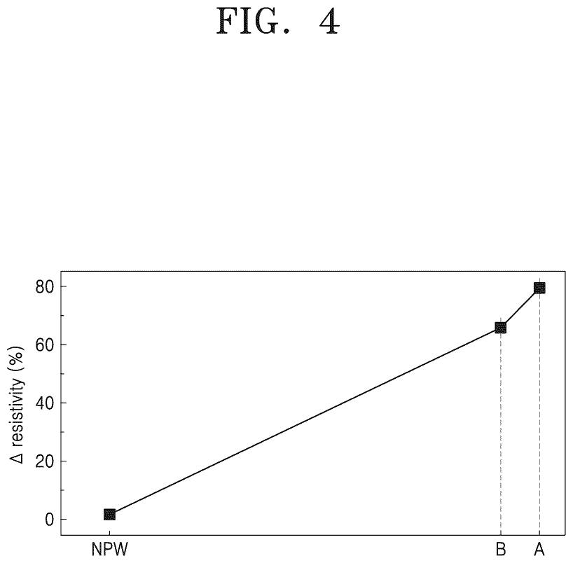

FIG. 2 is a cross-sectional view illustrating a schematic structure of an interconnect structure according to a comparative example. FIG. 3 is a microscopic photograph of a graphene layer included in the interconnect structure of FIG. 2. FIG. 4 is a graph showing a concept of a relationship between a width and resistivity of a graphene layer in the interconnect structure of FIG. 2.

Referring to FIG. 2, an interconnect structure 10 includes a conductive layer 15 formed inside a trench 11a formed in a dielectric layer 11, and the conductive layer 15 includes a plurality of graphene layers 15a. Unlike the embodiment, the graphene layers 15a are sequentially stacked from a bottom surface of the trench 11a. However, a relatively large number of scattering centers are formed in this structure, which may be disadvantageous in securing low resistivity.

The microscopic photograph of FIG. 3 is about a sample for observing resistivity according to a width w in a case where the graphene layers 15a are stacked in the form as illustrated FIG. 2.

In the graph of FIG. 4, sample A is a case where the width w is 40 nm, and sample B is a case where the width w is greater than 40 nm, namely, 100 nm. The graph of FIG. 4 shows an increase in resistivity compared to that of a reference sample, a non-patterned wafer (NPW), as the width w increases. The NPW is in an ideal state without edge scattering because there are no edges exposed because there is no pattern. In other words, compared to the width w of samples A and B, that is, 40 nm and 100 nm, a width of the NPW, the reference sample, may be regarded as infinite.

Referring to the graph, when patterns having the same width as samples B or A are formed, edge scattering is generated, increasing resistivity. Here, since a ratio of the exposed edge in the total area increases as the width w decreases, a change in resistivity increases due to the increase in the edge scattering as the width w decreases. In addition, when the width w is relatively small, the increase in resistivity according to the decrease in the width w is larger. This is because the scattering center that contributes to the increase in resistivity is mainly formed in an edge portion, and accordingly, the a degree of contribution of the scattering center increases with decreasing width w. As described, when the resistivity rapidly increases according to the width w, the resistance increases more rapidly, making it difficult to implement a wiring line width of, for example, 10 nm or less.

Unlike this, in the interconnect structure 100 according to the embodiment, as illustrated in FIG. 1, the plurality of graphene layers 150a filled in the trench 115 of the first dielectric layer 110 are stacked in a direction from a surface where the inner bottom surface and the inner side surfaces of the trench 115 are connected to each other, toward the center of the trench 115. This structure may have less scattering centers than the comparative example, and the increase in the resistivity due to the decrease in the line width of wires may be relatively small, and the rapid increase in the resistance may be prevented.

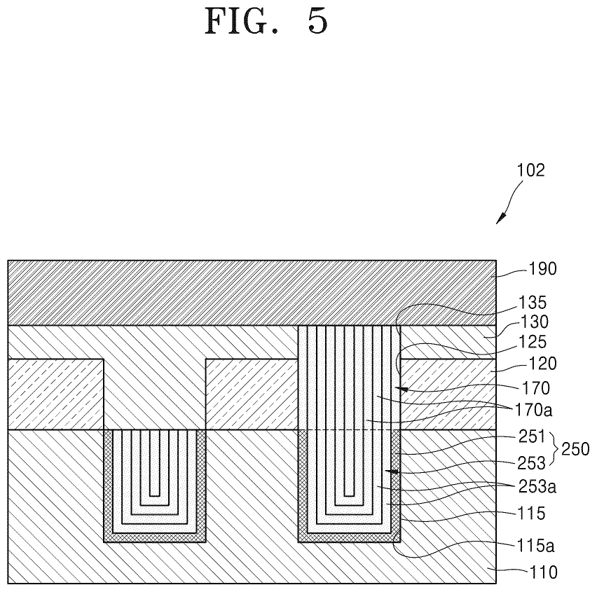

FIG. 5 is a cross-sectional view illustrating a schematic structure of an interconnect structure according to another embodiment.

An interconnect structure 102 of the present embodiment differs from the interconnect structure 100 of FIG. 1 in that the first conductive layer 150 formed in the trench 115 of the first dielectric layer 110 includes a metal layer 251 and a graphene layer 253.

The metal layer 251 may be conformally formed along the inner surface 115a of the trench 115, that is, the inner side surfaces and the inner bottom surface thereof. Then, a first graphene layer 253a may be conformally formed along a surface of the metal layer 251, and then a second graphene layer 253a may be formed, and in this manner, the plurality of graphene layers 253a may be sequentially formed in a direction toward the center of the trench 115.

The metal layer 251 may include, for example, Cu, Ru, Rh, Ir, Mo, W, Pd, Pt, Co, Ta, Ti, Ni, or Pd, but is not limited thereto.

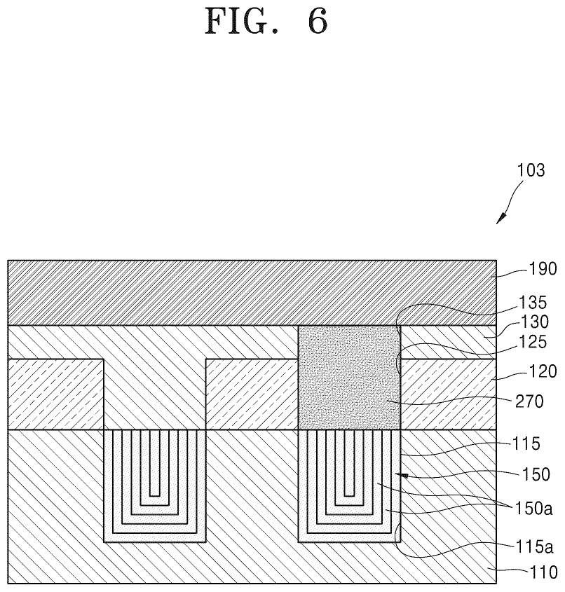

FIG. 6 is a cross-sectional view illustrating a schematic structure of an interconnect structure according to another embodiment.

An interconnect structure 103 of the present embodiment differs from the interconnect structure 100 of FIG. 1 in that a second conductive layer 270 formed in the through hole 125 of the second dielectric layer 120 includes a metal material. The second conductive layer 270 may include various metal materials such as Cu, Ru, Rh, Ir, Mo, W, Pd, Pt, Co, Ta, Ti, Ni, or Pd, but is not limited thereto.

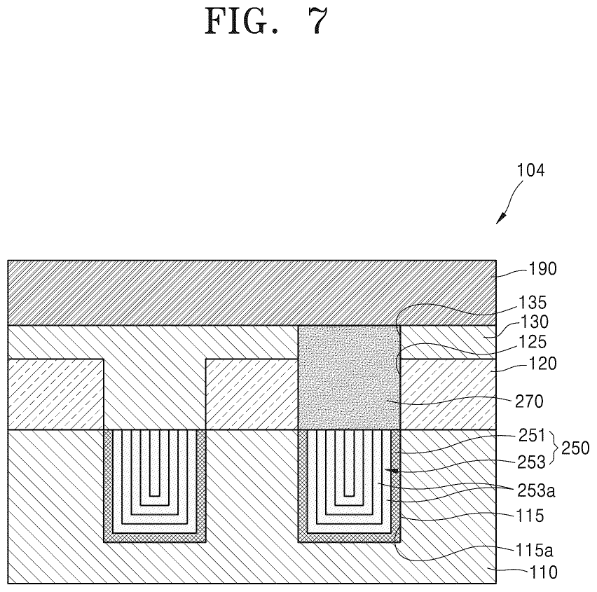

FIG. 7 is a cross-sectional view illustrating a schematic structure of an interconnect structure according to another embodiment.

An interconnect structure 104 of the present embodiment differs from the interconnect structure 100 of FIG. 1 in that the first conductive layer 150 formed in the trench 115 of the first dielectric layer 110 includes the metal layer 251 and the graphene layer 253, and the second conductive layer 270 formed in the through hole 125 of the second dielectric layer 120 includes a metal material.

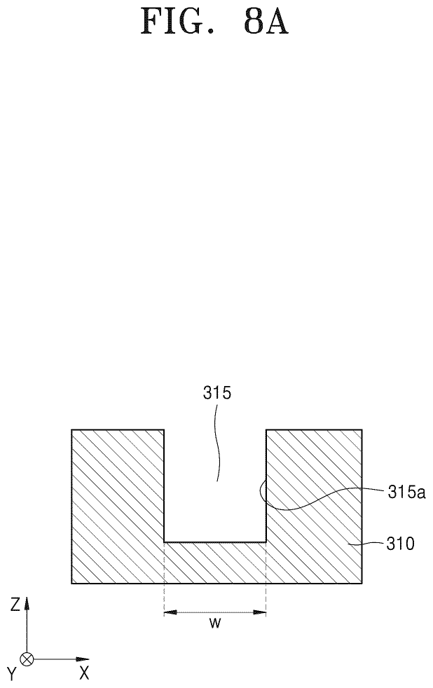

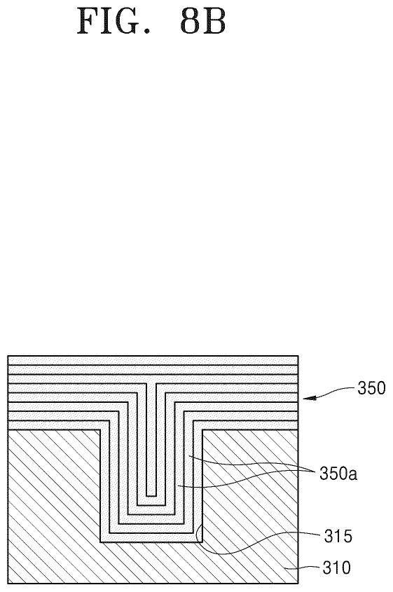

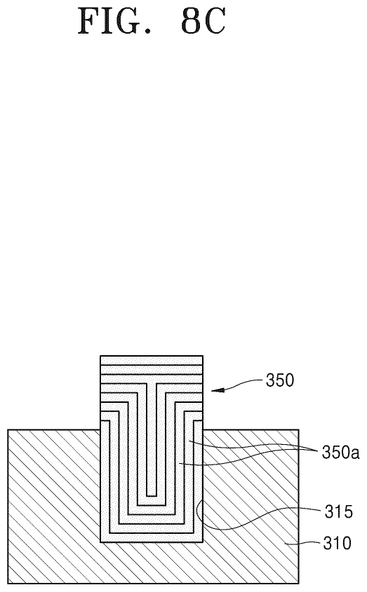

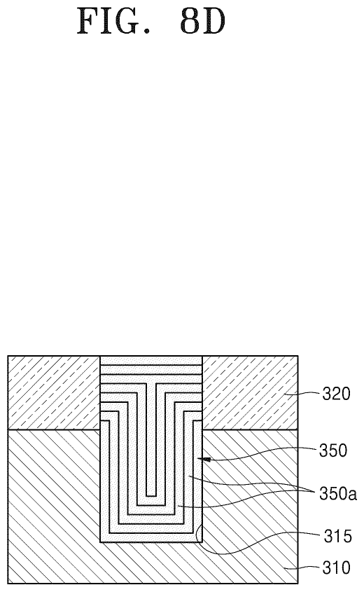

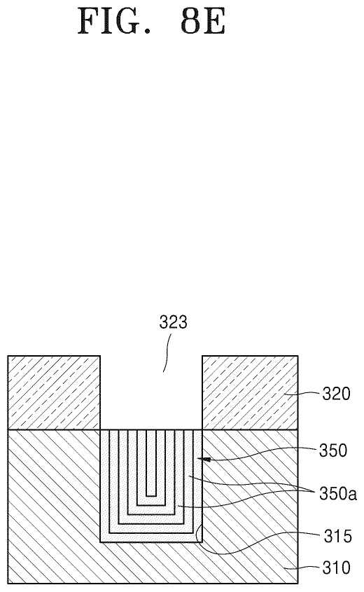

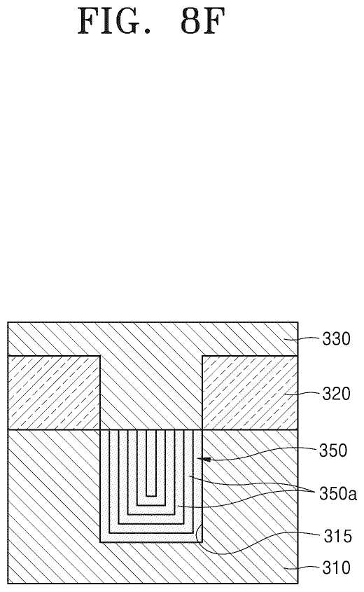

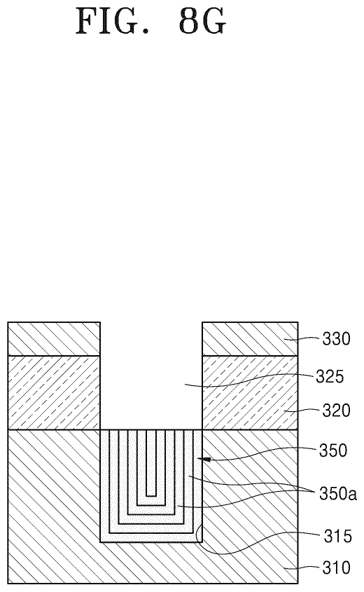

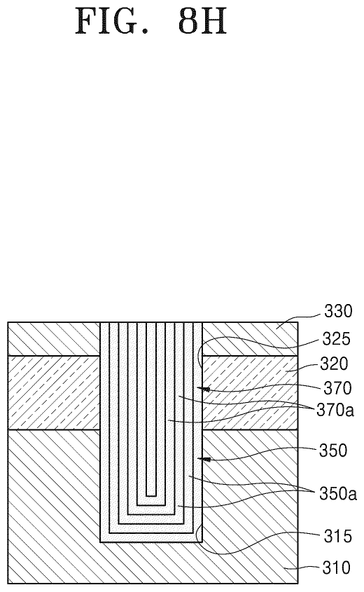

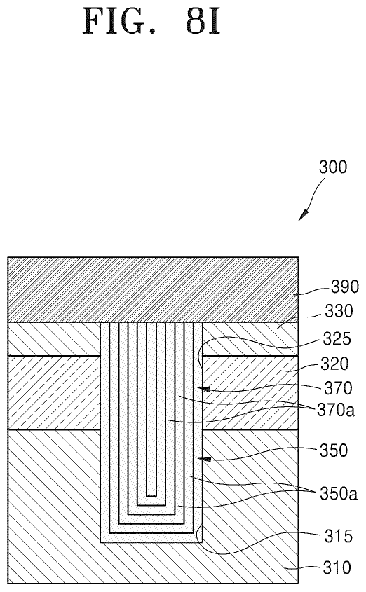

FIGS. 8A to 8I are diagrams for describing a method of manufacturing an interconnect structure, according to an embodiment.

Referring to FIG. 8A, a first dielectric layer 310 having a trench 315 formed therein is formed. The first dielectric layer 310 may include a dielectric material given as examples of the material of the first dielectric layer 110 in the description provided with reference to FIG. 1.

The trench 315 may be formed at a certain depth and with a desired width w, and an etching process such as a photolithograpy process or RIE process may be used to form the trench 315. The width w of the trench 315 may be, for example, about 20 nm or less or about 10 nm or less.

An inner surface 315a of the trench 315 is a surface including inner side surfaces and an inner bottom surface of the trench 315, and graphene may be conformally formed along the inner surface 315a.

Referring to FIG. 8B, a first conductive layer 350 including a plurality of graphene layers 350a extending inside the trench 315 and over an upper surface of the first dielectric layer 310 may be formed. The graphene layers 350a may be formed by chemical vapor deposition (CVD) or plasma enhanced CVD (PECVD). For PECVD, for example, capacitively coupled plasma (CCP), inductively coupled plasma (ICP), or microwave plasma may be used. Graphene included in the graphene layers 350a may include intrinsic graphene or nanocrystalline graphene given as examples in the above description of the graphene layers 150a, and may include metal-doped graphene or undoped graphene.

While the inside of the trench 315 is shown as completely filled with the graphene layers 350a in FIG. 8B, similar to that described with reference to FIG. 5, a first graphene layer 350a contacting the inner surface of the trench 315 and the upper surface of the first dielectric layer 310 may be replaced with a metal layer.

Referring to FIG. 8C, the first conductive layer 350 formed on the first dielectric layer 310 is patterned to correspond to the width of the trench 315. Photolithography and etching processes may be used in the patterning.

Referring to FIG. 8D, a second dielectric layer 320 is formed on the first dielectric layer 310. The second dielectric layer 320 may include a material given as examples of the material of the second dielectric layer 120 in the description with reference to FIG. 1.

The second dielectric layer 320 may be deposited on the first dielectric layer 310 by atomic layer deposition (ALD), CVD, PECVD, or the like. The dielectric material constituting the second dielectric layer 320 may be selectively deposited only on the first dielectric layer 310.

The graphene layers 350a extending above the trench 315 act as a self-inhibitor suitable for such selective deposition. For example, a dielectric material that is used in the first dielectric layer 310 and is suitable for an interlayer insulating film has a water contact angle (WCA) of about 30 degrees to about 40 degrees, whereas a WCA of graphene may be from about 60 degrees to about 110 degrees, or from about 90 degrees to about 110 degrees. A WCA of a material refers to an angle at which the material contacts water droplets at an air-liquid-solid interface. A large contact angle means that a material has a stable surface with relatively low surface energy. That is, the graphene layer 350a extending above the trench 315 may act as a mask in a deposition process of the second dielectric layer 320. In addition, since the graphene layers 350a having an sp² bonding structure have thermal stability even at a high temperature of about 400° C. to about 500° C., the graphene layers 350a may stably act as a mask even in a high-temperature ALD or CVD process.

In the selective deposition process, the graphene layers 350a protruding above the trench 315 may additionally include atoms having relatively high electronegativity in order to further lower surface energy. For example, the graphene layers 350a may further include F, Cl, Br, N, P or O atoms. A concentration of the added atoms may be approximately 0.1 at % to about 10 at % (atomic percent), but is not limited thereto. In this case, the graphene layers 350a may have a higher contact angle than when the atoms described above are not added. For example, a contact angle of nanocrystalline graphene without F atoms was measured to be approximately 90.6 degrees, and a contact angle of nanocrystalline graphene including F atoms was measured to be approximately 102.1 degrees. The WCA of graphene indicates that graphene may function as a self-inhibitor, that is, a FAV process may be performed without using a separate inhibitor. In other words, the second dielectric layer 320 may be selectively formed only on the first dielectric layer 310 without being formed on the first conductive layer 350 which protrudes above the trench 315.

Next, as illustrated in FIG. 8E, a portion of the first conductive layer 350, which protrudes above the trench 315, may be removed. An etching or ashing process may be used as a removal process, and for example, an oxygen plasma (O₂ plasma) process or a hydrogen plasma (H₂ plasma) process may be used. As illustrated in FIG. 8E, a through hole 323 that is well aligned with the trench 315 formed in the first dielectric layer 310 may be formed. The graphene layers 350a formed inside the trench 315 may be exposed by the through hole 323.

Referring to FIG. 8F, a third dielectric layer 330 may be formed to extend above the second dielectric layer 320 while filling the through hole 323 of the second dielectric layer 320. The third dielectric layer 330 includes an IMD of a different level from that of the first dielectric layer 310, and may include a material given as examples as the third dielectric layer 130 in the description of FIG. 1. The third dielectric layer 330 may be formed by a method such as ALD, CVD, PECVD, or the like.

Next, the third dielectric layer 330 is patterned and etched, and as illustrated in FIG. 8G, the through hole 125 penetrating the second dielectric layer 320 and the third dielectric layer 330 to be connected to the trench 315 is formed.

Referring to FIG. 8H, a second conductive layer 370 is formed inside the through hole 125. The second conductive layer 370 may include a plurality of graphene layers 370a. Next, as illustrated in FIG. 8I, a third conductive layer 390 connected to the second conductive layer 370 may be formed on the third dielectric layer 330. The third conductive layer 390 may include various conductive materials such as metal, metal alloy, or graphene. Examples of the methods of forming the third conductive layer 390 may include CVD, PECVD, physical vapor deposition (PVD), ALD, sputtering, and electroplating, chemical solution deposition, or electroless plating.

In the process of FIG. 8H, the second conductive layer 370 may include a metal material instead of graphene. The second conductive layer 370 and the third conductive layer 390 may include the same metal material, and in this case, the processes of FIGS. 8H and 8I may be performed together.

Through this process, an interconnect structure 300 may be manufactured. A major shape of the interconnect structure 300 manufactured as above is similar to that of the interconnect structure 100 of FIG. 1. However, by referring to the methods described above, structures of the interconnect structures 102, 103, and 104 described with reference to FIGS. 5 to 7 may be easily manufactured.

The interconnect structures 100, 102, 103, 104, and 300 described above may be utilized to provide a wiring structure in various electronic devices.

The electronic devices may include, for example, a memory device, a logic device, an image sensor, or an integrated circuit device, and are not particularly limited.

The electronic devices may include, for example, a substrate and any one of the interconnect structures 100, 102, 103, 104, and 300 described above and formed on the substrate, or an interconnect structure that is formed by a combination or modification thereof.

The substrate may include at least one type of a Group IV semiconductor material, a semiconductor compound, an insulating material, and a metal. For example, the substrate may include a Group IV semiconductor material such as Si, Ge or Sn. Alternatively, for example, the substrate may include at least one type of Si, Ge, C, Zn, Cd, Al, Ga, In, B, C, N, P, S, Se, As, Sb, Te Ta, Ru, Rh, Ir, Co, Ta, Ti, W, Pt, Au, Ni, and Fe. For example, the substrate may include Si, Ge, SiC, SiGe, SiGeC, Ge alloy, GaAs, InAs, InP, and the like. The substrate may include a single layer or multiple layers in which different materials are stacked. For example, the substrate may include a silicon-on-insulator (SOI) substrate or a silicon germanium-on-insulator (SGOI) substrate. For example, the substrate may further include N and F as a SiCOH-based composition, and may include pores to lower permittivity. The substrate may further include a dopant.

The substrate may include a semiconductor pattern, a metal pattern, or an insulating pattern, and these patterns may include a semiconductor layer, a metal layer, or an insulating layer, either as a single layer or multiple layers. One or more semiconductor devices or circuit elements may be included in the substrate; for example, a transistor, a capacitor, a diode, or a resistor may be included in the substrate. These elements may be electrically connected with wires having fine line widths by using the interconnect structure according to the embodiment.

The interconnect structures described above and a device including the same have been described with reference to the embodiment shown in the drawings, but these are merely an example, and it will be understood by those skilled in the art that various modifications and equivalents thereto can be made. The disclosed embodiments should thus be considered in a descriptive sense only and not for purposes of limitation. The scope of the disclosure is defined not by the detailed description of the disclosure but by the appended claims, and all differences within the scope will be construed as being included in the disclosure.

According to the interconnect structures described above, misalignment hardly occurs, and the increase in the resistivity due to the decrease in line widths may be reduced.

According to the interconnect structures described above, a graphene layer may act as a self-inhibitor, and thus, the manufacture using a FAV process may be performed.

The interconnect structures described above may be applied to form wires having fine line widths in various electronic devices.

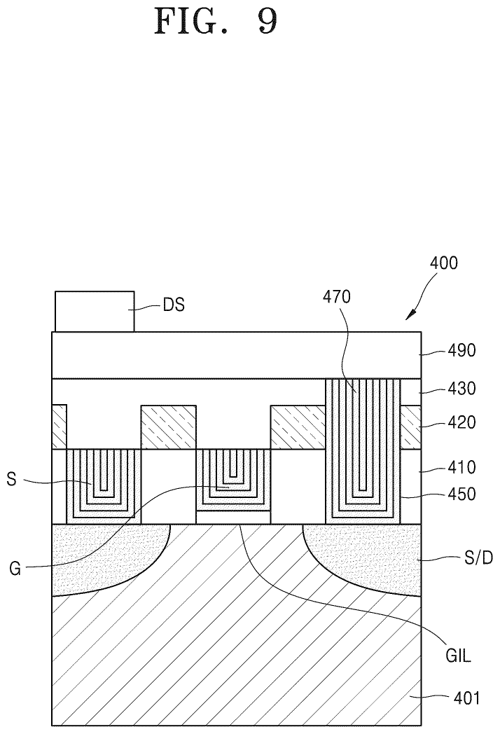

FIG. 9 is a cross-sectional view of a memory device according to an embodiment.

Referring to FIG. 9, a memory device 400 may include a substrate 401 including source/drain regions S/D spaced apart from each other. Top surfaces of the source/drain regions S/D may be coplanar with an upper surface of the substrate 410. The source/drain regions S/D may have a different conductivity type than a portion of the substrate 401 surrounding the source/drain regions S/D. A first dielectric layer 410 may be on the substrate and may include through-holes that expose the source/drain regions S/D. A source electrode S and a first conductive layer 450 may be in the through-holes of the first dielectric layer 410 that expose the source/drain regions S/D. A gate insulating layer GIL and a gate electrode G may be in a through-hole of the first dielectric layer 410 that exposes a portion of the substrate 401 between the source/drain regions S/D. A second dielectric layer 420 may be on the first dielectric layer 410 and may have through-holes that expose the source electrode S, gate electrode G, and first conductive layer 450. A third dielectric layer 430 may be on the second dielectric layer 420 and may include a through-hole over first conductive layer 450. A second conductive layer 470 may be on the first conductive layer 450 and extend through the third dielectric layer 430 and second dielectric layer 420 to contact the first conductive layer 450. A third conductive layer 490 may be on the third dielectric layer 430 and may contact a top surface of the second conductive layer 470. A data storage DS, such as a capacitor, may be on the third conductive layer 490. The data storage DS may be electrically connected to one of the source/drain regions S/D through the third conductive layer 490, second conductive layer 470, and first conductive layer 450. Materials for the first dielectric layer 410, second dielectric layer 420, and third dielectric layer 430 may be the same as the materials for the first dielectric layer 110, second dielectric layer 120, and third dielectric layer 130 in FIG. 1, respectively. The third conductive layer 190 and 490 in FIGS. 1 and 9 may be formed of the same material. The first conductive layer 450, source electrode S, and gate electrode G may include an electrically conductive material and may be formed of the same materials as any one of the first conductive layers 150, 250, and 350 described above in FIGS. 1, 5, 6, 7, and 8. The second conductive layer 470 may include an electrically conductive material, such as any one of the second conductive layers 170, 270, and 370 described above in FIGS. 1, 5, 6, 7, and 8.

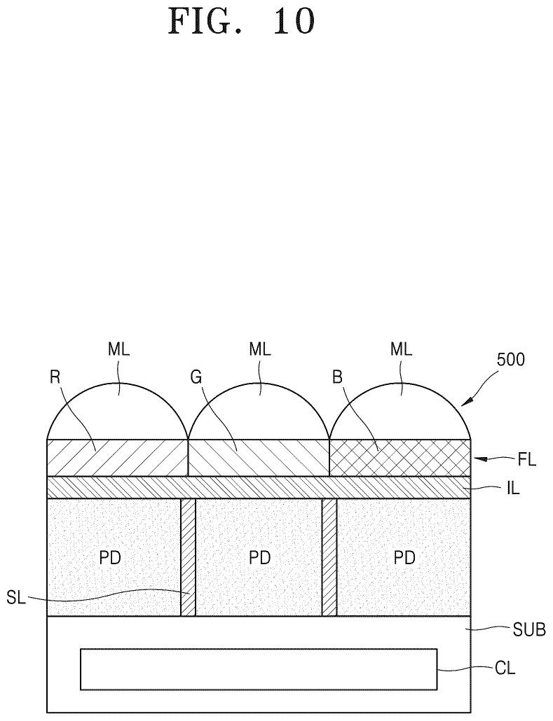

FIG. 10 is a cross-sectional view of an image sensor according to an embodiment.

Referring to FIG. 10, an image sensor may include a substrate SUB, such as silicon substrate, and a plurality of photodiodes PD separated from each other by separation layers SL in an upper region of the substrate SUB. A circuit layer CL may be formed in the substrate SUB below the plurality of photodiodes PD. An insulating layer IL may be formed on the plurality of photodiodes PD. A filter layer FL may be formed on the insulating layer IL and may include red R, green G, and blue B filters over corresponding photodiodes PD. Microlenses ML may be formed on the filter layer FL and may include a corresponding microlens ML over each corresponding photodiode PD. The circuit layer CL may include any one of the interconnect structures 100, 102, 103, 104, and 300 described above.

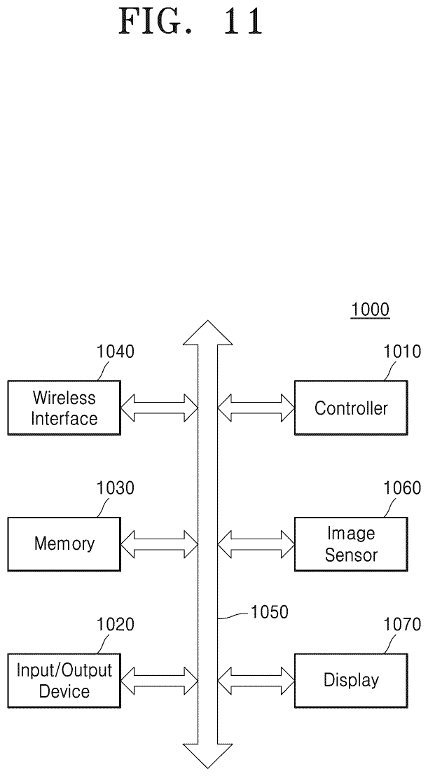

FIG. 11 is a diagram of an electronic device according to an embodiment.

Referring to FIG. 11, the electronic device 1000 may constitute a wireless communication device or a device capable of transmitting and/or receiving information in a wireless environment. The electronic device 1000 may include a controller 1010, an input/output device (I/O) 1020, a memory 1030, and a wireless interface 1040, and these components may be interconnected to each other through a bus 1050. Optionally, the electronic device 1000 may further include an image sensor 1060 and/or a display 1070 connected to the bus 1050.

The controller 1010 may include at least one of a microprocessor, a digital signal processor, and a processing device similar thereto. The I/O device 1020 may include at least one of a keypad, a keyboard, and a display. The memory 1030 may be used to store instructions executed by controller 1010. For example, the memory 1030 may be used to store user data. The electronic device 1000 may use the wireless interface 1040 to transmit/receive data through a wireless communication network. The wireless interface 1040 may include an antenna and/or a wireless transceiver. In some embodiments, the electronic device 1000 may be used in a communication interface protocol of a third-generation communication system such as code division multiple access (CDMA), global system for mobile communications (GSM), north American digital cellular (NADC), extended-time division multiple access (E-TDMA), wide band code division multiple access (WCDMA), a 4G (4th Generation) communication system such as 4G LTE, a 5G (5th Generation) communication system, a wired local area network (LAN), a wireless local area network (WLAN), such as Wi-Fi (Wireless Fidelity), a wireless personal area network (WPAN), such as Bluetooth, Wireless USB (Wireless Universal Serial Bus), Zigbee, Near Field Communication (NFC), Radio-frequency identification (RFID), and/or Power Line communication (PLC).

The electronic device 1000 may include any one of the interconnect structures 100, 102, 103, 104, and 300 described above in the controller 1010, input/output device 1020, memory 1030, wireless interface 1040, image sensor 1060, or display 1070. The memory 1030 may include memory device 400 described above. The image sensor 1060 may include the image sensor 500 described above.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An interconnect structure comprising:
a first dielectric layer including a trench;
a first conductive layer in the trench, the first conductive layer including a plurality of first graphene layers stacked in a direction from an inner surface of the trench toward a center of the trench;
a second dielectric layer on the first dielectric layer, the second dielectric layer including a through hole extending to the trench; and
a second conductive layer in the through hole.

2. The interconnect structure of claim 1, wherein the second conductive layer comprises a plurality of second graphene layers.

3. The interconnect structure of claim 1, wherein the second conductive layer comprises a metal material.

4. The interconnect structure of claim 1, wherein
the first conductive layer further comprises a metal layer contacting the inner surface of the trench.

5. The interconnect structure of claim 4, wherein the second conductive layer comprises a plurality of second graphene layers.

6. The interconnect structure of claim 4, wherein the second conductive layer comprises a metal material.

7. The interconnect structure of claim 1, wherein the first dielectric layer comprises a dielectric material having a dielectric constant of 3.6 or less.

8. The interconnect structure of claim 7, wherein the second dielectric layer comprises a dielectric material that is selectively depositable on the first dielectric layer.

9. The interconnect structure of claim 7, further comprising:
a third dielectric layer on the second dielectric layer,
wherein the second dielectric layer and the third dielectric layer define the through hole such that through hole extends through the second dielectric layer to the third dielectric layer and penetrates through the third dielectric layer, and
the second conductive layer fills the through hole.

10. The interconnect structure of claim 9, wherein the third dielectric layer comprises a dielectric material having a dielectric constant of 3.6 or less.

11. The interconnect structure of claim 1, wherein a width of the trench is equal to or less than 10 nm.

12. The interconnect structure of claim 1, wherein the plurality of first graphene layers comprise intrinsic graphene or nanocrystalline graphene.

13. The interconnect structure of claim 12, wherein the nanocrystalline graphene comprises crystals having a size of about 0.5 nm to about 500 nm.

14. The interconnect structure of claim 12, wherein, in the nanocrystalline graphene, a ratio of carbons having an sp² bond structure to total carbons is about 50% to about 99%.

15. The interconnect structure of claim 12, wherein the nanocrystalline graphene comprises hydrogen of about 1 at % to about 20 at %.

16. The interconnect structure of claim 12, wherein the nanocrystalline graphene has a density of about 1.6 g/cc to about 2.1 g/cc.

17. The interconnect structure of claim 12, surface of crystals of the nanocrystalline graphene is substantially perpendicular to a direction of stacking of the plurality of the first graphene layers.

18. An electronic device comprising:
a substrate; and
an interconnect structure on the substrate,
wherein the interconnect structure includes
a first dielectric layer including a trench,
a first conductive layer in the trench,
a second dielectric layer on the first dielectric layer, and
a second conductive layer,
wherein the first conductive layer includes a plurality of first graphene layers stacked in a direction from an inner surface of the trench toward a center of the trench, the second dielectric layer includes a through hole extending to the trench, and the second conductive layer is in the through hole.

19. The electronic device of claim 18, wherein the second conductive layer comprises a plurality of graphene layers or a metal material.

20. The electronic device of claim 18, wherein
the interconnect structure further comprises a third dielectric layer on the second dielectric layer, and
the second dielectric layer and the third dielectric layer define the through hole such that the through hole extends through the second dielectric layer to the third dielectric layer and penetrates through the third dielectric layer, and
the second conductive layer fills the through hole.
